(19) United States
(12) Patent Application Publication
(10) Pub. No.: US 2012/0256165 A1
(43) Pub. Date: Oct. 11, 2012

(54) SINGLE-QUANTUM DOT DEVICE AND METHOD OF MANUFACTURING THE SAME

(75) Inventor: Hong Seok LEE, Buk-gu (KR)

(73) Assignee: GWANGJU INSTITUTE OF SCIENCE AND TECHNOLOGY, Buk-gu (KR)

(21) Appl. No.: 13/325,671

(22) Filed: Dec. 14, 2011

(30) Foreign Application Priority Data
Apr. 5, 2011 (KR) 10-2011-0031358

(51) Int. Cl. H01L 29/66; H01L 21/04; B82Y 40/00; B82Y 99/00

(52) U.S. Cl. 257/14; 438/478; 977/840; 257/E29.168; 257/E21.04; 977/774

(57) ABSTRACT

The present disclosure provides a single-quantum dot device and a method of manufacturing the same. A transparent dielectric thin film is formed on a cover layer and an energy band of quantum dots is adjusted based on compressive stress due to difference in coefficient of thermal expansion therebetween. Specifically, the dielectric thin film has a lower coefficient of thermal expansion than the cover layer and compressive stress is applied to the cover layer by radiation of laser beams. Then, the quantum dots undergo compressive stress and the energy band of the quantum dots increases with increasing intensity of the laser beams.

### CROSS-REFERENCE TO RELATED APPLICATION

This application claims the benefit under 35 U.S.C. §119 of Korean Patent Application No. 10-2011-0031358, filed on Apr. 5, 2011 in the Korean Intellectual Property Office, the entirety of which is incorporated herein by reference.

### BACKGROUND

1. Technical Field

The present invention relates to optical devices, and more particularly, to a single-quantum dot device and a method of manufacturing the same.

2. Description of the Related Art

Semiconductor nanostructures are generally classified into quantum well structures and quantum dot structures.

The quantum well structure refers to a structure in which a well layer having lower band gap energy is interposed between upper and lower barrier layers having higher band gap energy. In such a quantum well structure, the well layer has no degree of freedom in the vertical direction and may move relatively freely in the horizontal direction. Thus, this structure is also referred to as a two-dimensional quantum structure. In recent years, the quantum well structure has been actively applied to a light emitting layer of a light emitting diode. The light emitting diode may emit a high brightness of light through quantum refinement obtained by the structure wherein barrier layers and well layers are alternately stacked one above another. Further, the light emitting diode may adjust the wavelengths of emitted light through regulation of the band gap of the well layer. Most semiconductor lasers have such a quantum well structure.

The quantum dot structure has a zero-dimensional quantum structure. Further, the quantum dot structure is subjected to quantum mechanical refinement in all directions and has a discontinuous energy structure like an atom. In particular, a single-quantum dot structure wherein quantum dots demonstrate identical optical characteristics is applied to nano optoelectronic devices such as a single-electron memory, a single-photon light source, and the like. Among the nano optoelectronic devices, a single-photon emitter is a representative single-quantum dot light source, which has an essential feature in realization of quantum cryptography or a quantum computer.

Further, a single-photon emitter using a compound semiconductor formed on a silicon substrate can realize low cost and high gain, and thus is actively studied in the art.

In order to manufacture such a single-quantum dot structure, it is essential to achieve control of an accurate energy band of quantum dots. Furthermore, in order to secure substantial integrity, it is important to control the size and shape of quantum dots during growth of the quantum dots.

However, in a current technique for forming quantum dots, a compound semiconductor layer is formed on a substrate and subjected to photolithographic patterning to obtain a regular arrangement of the quantum dots. Since this technique requires uniform deposition of the compound semiconductor and the lithography process, it involves many problems relating to increase in manufacturing cost and process complexity.

Therefore, there is a need for a technique capable of forming quantum dots and regulating the energy band of preformed quantum dots.

### BRIEF SUMMARY

The present invention provides a single-quantum dot device capable of regulating an energy band of a quantum dot structure.

The present invention also provides a method of manufacturing a single-quantum dot device according to the present invention.

In accordance with an aspect of the present invention, a single-quantum dot device includes a buffer layer formed on a substrate and including a compound semiconductor; quantum dots formed on the buffer layer; a cover layer embedding the quantum dots therein; and a dielectric thin film formed on the cover layer and having a lower coefficient of thermal expansion than the cover layer.

In accordance with another aspect of the present invention, a method of manufacturing a single-quantum dot device includes sequentially forming a buffer layer, quantum dots, a cover layer and a dielectric thin film on a substrate; and irradiating a laser beam to the dielectric thin film and the cover layer to adjust an energy band of the quantum dots.

### BRIEF DESCRIPTION OF THE DRAWINGS

The above and other aspects, features, and advantages of the invention will become apparent from the detailed description of following exemplary embodiments in conjunction with the accompanying drawings;

FIG. 1 is a sectional view of a single-quantum dot device in accordance with one exemplary embodiment of the present invention;

FIG. 2 is a flowchart of a method of manufacturing a single-quantum dot device in accordance with one exemplary embodiment of the present invention;

FIG. 3 is a graph depicting optical characteristics of quantum dot device samples manufactured by the method of FIG. 2 in accordance with the exemplary embodiment of the present invention; and

FIG. 4 is a graph depicting blue shift of an energy band by radiation of laser beams to the device samples of FIG. 3.

### DETAILED DESCRIPTION

Next, exemplary embodiments of the present invention will be described with reference to the accompanying drawings. It should be understood that the present invention is not limited to the following embodiments and may be embodied in different ways, and that the embodiments are given to provide complete disclosure of the invention and to provide thorough understanding of the invention to those skilled in the art. The scope of the invention is limited only by the accompanying claims and equivalents thereof. Like components will be denoted by like reference numerals throughout the specification.

Unless otherwise defined herein, all terms including technical or scientific terms used herein have the same meanings as commonly understood by those skilled in the art to which the present invention belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein.

### Embodiments

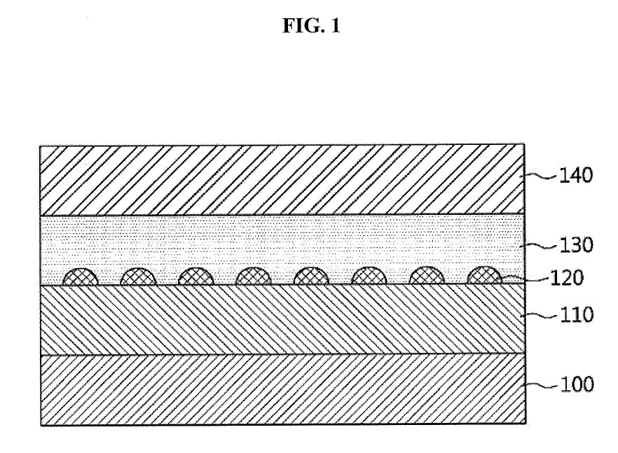

FIG. 1 is a sectional view of a single-quantum dot device in accordance with one exemplary embodiment of the present invention.

Referring to FIG. 1, the single-quantum dot device includes a substrate 100, a buffer layer 110, quantum dots 120, a cover layer 130, and a dielectric thin film 140.

The substrate 100 may be formed of any material which allows growth of the buffer layer 110 thereon. For example, the substrate 100 may be a semiconductor substrate and may be formed of a transparent material. The semiconductor substrate may be composed of Si or GaAs. Further, the transparent substrate may be a sapphire substrate. As such, there is no particular restriction as to the material of the substrate 100.

The buffer layer 110 is formed on the substrate 100. The buffer layer 110 is composed of a material which may facilitate and induce formation of the quantum dots 120. For example, the buffer layer 110 may include ZnTe.

The quantum dots 120 are formed on the buffer layer 110. The quantum dots 120 are formed in a pattern of individual quantum dots and comprise CdTe. Further, the quantum dots may be separated constant intervals from each other to have a regular arrangement.

The cover layer 130 is formed on the quantum dots. The cover layer 130 may be composed of the same material as that of the buffer layer 110. Thus, when the buffer layer 110 comprises ZnTe, the cover layer 130 may also comprise ZnTe.

The dielectric thin film 140 is formed on the cover layer 130. The dielectric thin film 140 may be composed of any transparent material which has a different coefficient of thermal expansion than the cover layer 130. For example, silicon oxide, which facilitates layer formation and has a high degree of transparency, may be used for the dielectric thin film 140. In particular, the dielectric thin film 140 may have a lower coefficient of thermal expansion than the cover layer 130.

Further, the cover layer 130 undergoes compressive stress caused by difference in the coefficient of thermal expansion between the cover layer 130 and the dielectric thin film 140. Such compressive stress is transferred to the quantum dots, thereby causing an increase in energy band gap of the quantum dots. That is, as the size of the quantum dot 120 decreases, the quantum dots increase in band gap energy. Here, the band gap of the quantum dots increases due to the compressive stress transferred from the cover layer 130.

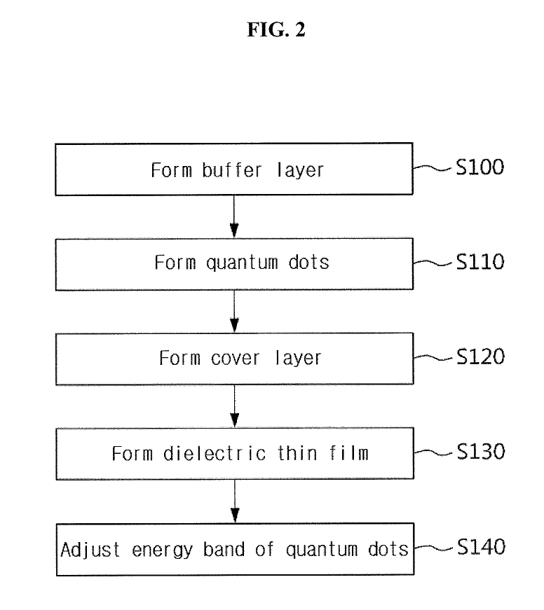

FIG. 2 is a flowchart of a method of manufacturing a single-quantum dot device in accordance with one exemplary embodiment of the present invention.

Referring to FIG. 2, a buffer layer is formed on a silicon substrate (S100).

First, formation of the buffer layer on the silicon substrate is carried out by molecular beam epitaxy (MBE). By this process, the buffer layer of ZnTe is formed. The temperature of the substrate is set to 320° C., the temperature of a Zn containing gas is set to 280° C., and the temperature of a Te containing gas is set to 300° C. The buffer layer is grown to a thickness of 900 nm for two hours.

Then, quantum dots are formed on the buffer layer (S110).

The quantum dots have a composition of CdTe and are formed by atomic layer deposition. First, a Cd containing gas is supplied for 8 seconds. Then, supply of the Cd containing gas is blocked, and a Te containing gas is supplied for 8 seconds. Here, the temperature of the substrate is set to 320° C., the temperature of the Cd containing gas is set to 195° C., and the temperature of the Te containing gas is set to 300° C.

Through this process, the quantum dots are formed on the buffer layer.

Then, a cover layer is formed so as to embed the quantum dots therein (S120).

The cover layer is formed under substantially the same conditions as those for forming of the buffer layer. Here, the cover layer is grown to a thickness of 100 nm for 15 minutes.

Then, a dielectric thin film is formed on the cover layer (S130).

The dielectric thin film is composed of silicon oxide. Formation of silicon oxide is carried out through electron beam deposition. Through this process, a 200 nm thick silicon oxide is formed.

Then, after forming the dielectric thin film, the energy band of the quantum dots is controlled (S140).

The energy band of the quantum dots is carried out by generating compressive stress resulting from difference in the coefficient of thermal expansion between the dielectric thin film and the cover layer. Thus, energy is applied to the device from outside to generate compressive stress. In this embodiment, a laser beam is used. The temperatures of the cover layer and the dielectric thin film increase upon radiation of the laser beam, and compressive stress is generated in the cover layer as temperature increases. The compressive stress of the cover layer is transferred to the quantum dots, so that the energy band of the quantum dots may be adjusted.

For example, silicon oxide constituting the dielectric thin film has a coefficient of thermal expansion of 0.52×10⁻⁶/° C., and ZnTe constituting the cover layer has a coefficient of thermal expansion of 8.40×10⁻⁶/° C. Thus, when temperature increases, the cover layer has more expansion factors than the dielectric thin film. Thus, the cover layer undergoes compressive stress caused by difference in the coefficient of thermal expansion between the dielectric thin film and the cover layer. In this manner, the energy band of the quantum dots may be adjusted.

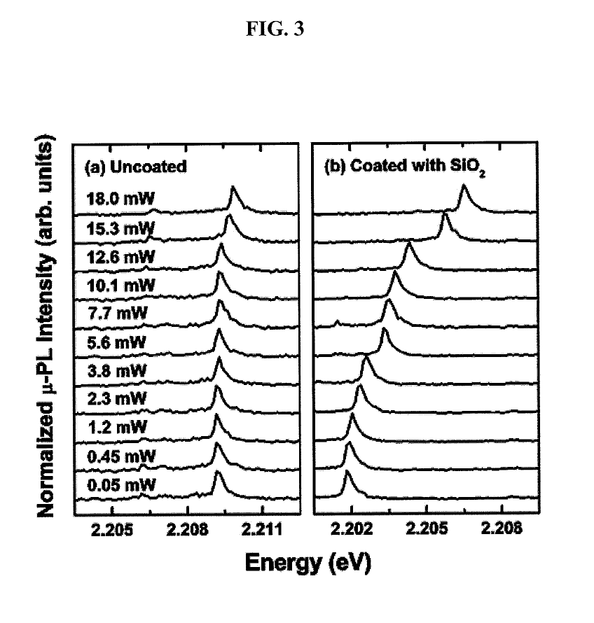

FIG. 3 is a graph depicting optical characteristics of single-quantum dot device samples manufactured by the method of FIG. 2 in accordance with the embodiment of the present invention.

Referring to FIG. 3, two device samples are prepared. Specifically, one sample does not include a dielectric thin film and the other sample includes the dielectric thin film.

The left graph of FIG. 3 is a photoluminescence graph of the sample which does not include the dielectric thin film, and the right graph of FIG. 3 is a photoluminescence graph of the sample which includes the dielectric thin film. A laser beam was irradiated to both samples for 5 seconds while increasing laser power from 0.05 mW to 18 mW.

With a laser spot set to have a size of about 1.5 um at 10K, a laser beam was irradiated at an initial laser power of 0.05 mW for 5 seconds. Then, the laser power was lowered to 50 uW and photoluminescence was measured.

Then, with the laser power increased to 0.45 mW, the laser beam was irradiated for 5 seconds, and the laser power was lowered again to 50 uW, followed by measurement of photoluminescence. In this method, the laser power was increased up to 18 mW.

In the left graph of FIG. 3, it can be seen that variation of peaks in the spectrum is insignificant even after the laser power is increased. In other words, it can be seen that there is substantially no change in the energy band of the quantum dots.

Further, in the right graph of FIG. 3, it can be seen that the energy band of the quantum dots increases when the laser beam is irradiated while increasing the laser power. From this result, it can be seen that compressive stress is applied to the quantum dots upon radiation of laser beams, thereby changing the energy band thereof.

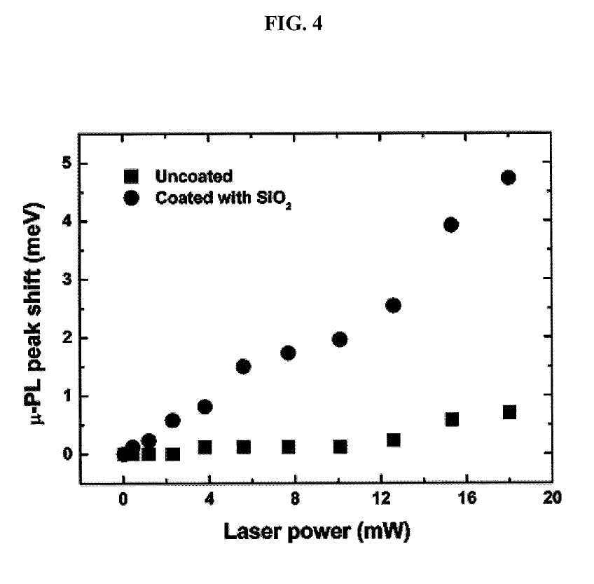

FIG. 4 is a graph depicting blue shift of an energy band by radiation of laser beams to the device samples of FIG. 3.

Referring to FIG. 4, in the sample which does not include the dielectric thin film, there was substantially no change of the peaks of photoluminescence even when the laser power was increased. On the other hand, in the single-quantum dot device coated with silicon oxide, it can be seen that the peak increases with increasing laser power. As a result, it can be seen that blue shift of the energy band occurred by radiation of a laser beam.

In this embodiment, shift of the energy band through radiation of laser beams in the CdTe/ZnTe single-quantum dot structure is disclosed. However, adjustment of the energy band according to compressive stress may also be applied to a quantum well structure which is composed of a group III-V compound semiconductor and a group II-VI compound semiconductor. Thus, the structure including the buffer layer, the quantum dots and the cover layer may be equivalently replaced by the structure of barrier layer/well layer/barrier layer of a group III-V compound semiconductor or a group II-VI compound semiconductor. That is, in a quantum well structure composed of a compound semiconductor such as InAs, InP, GaN, InN, GaP, CdTe, CdS, CdSe, ZnTe, ZnSe or ZnS, it is possible to adjust the energy band by adjusting compressive stress.

As such, according to the embodiments, the energy band of the quantum dots may be adjusted by adjusting laser power and laser radiation time, and change of a wavelength band to a certain color may be easily induced. In particular, a single-quantum dot device may be applied to single-photon emitters or light emitting devices which generate light in a certain wavelength band.

Although some embodiments have been described herein, it should be understood by those skilled in the art that these embodiments are given by way of illustration only, and that various modifications, variations, and alterations can be made without departing from the spirit and scope of the invention. Therefore, the scope of the invention should be limited only by the accompanying claims and equivalents thereof.

What is claimed is:

1. A single-quantum dot device comprising:
a buffer layer formed on a substrate and including a compound semiconductor;
quantum dots formed on the buffer layer;
a cover layer embedding the quantum dots therein; and
a dielectric thin film formed on the cover layer and having a lower coefficient of thermal expansion than the cover layer.

2. The single-quantum dot device of claim 1, wherein the cover layer is subjected to compressive stress due to a higher coefficient of thermal expansion than the dielectric thin film and transfers the compressive stress to the quantum dots.

3. The single-quantum dot device of claim 2, wherein the cover layer is subjected to compressive stress upon radiation of laser beams thereto and an energy band of the quantum dots is increased by the compressive stress.

4. The single-quantum dot device of claim 1, wherein the cover layer is formed of the same material as that of the buffer layer, and comprises ZnTe.

5. The single-quantum dot device of claim 4, wherein the quantum dots comprise CdTe.

6. A method of manufacturing a single-quantum dot device comprising:
sequentially forming a buffer layer, quantum dots, a cover layer and a dielectric thin film on a substrate; and
irradiating a laser beam to the dielectric thin film and the cover layer to adjust an energy band of the quantum dots.

7. The method of claim 6, wherein the cover layer has a lower coefficient of thermal expansion than the cover layer and is made of a transparent material.

8. The method of claim 6, wherein the cover layer is subjected to compressive stress upon radiation of laser beams thereto and an energy band of the quantum dots is increased by the compressive stress.
